(19) United States
(12) Patent Application Publication
(10) Pub. No.: US 2026/0143890 A1
(43) Pub. Date: May 21, 2026

(54) MICRO-LED MODULE AND DISPLAY DEVICE COMPRISING SAME

(71) Applicant: LG ELECTRONICS INC., Seoul (KR)

(72) Inventors: Hyunjong KIM, Seoul (KR); Jeongsik CHOI, Seoul (KR); Jihoon LEE, Seoul (KR); Seunghwan CHA, Seoul (KR); Gwangho CHOI, Seoul (KR)

(73) Assignee: LG ELECTRONICS INC., Seoul (KR)

(21) Appl. No.: 19/119,363

(22) PCT Filed: Sep. 19, 2023
(86) PCT No.: PCT/KR2023/014112

§ 371 Date: Apr. 8, 2025

(30) Foreign Application Priority Data
Oct. 27, 2022 (KR) 10-2022-0140495

(51) Int. Cl. H10H 29/855; H10H 29/24; H10H 29/853

(52) U.S. Cl. CPC H10H 29/855; H10H 29/24; H10H 29/853

(57) ABSTRACT

This micro-LED module comprises: a unit substrate; a plurality of micro-LED chips mounted on the upper surface of the unit substrate; a protection film for covering the upper surface of the unit substrate and the plurality of micro-LED chips; a black film provided on the upper surface of the protection film; and an optical material provided on the upper surface of the black film, wherein the micro-LED module, having a transparent polymer material, includes the optical material including the transparent polymer material on the upper surface of the black film, and the polymer material has a high refractive index or at least a predetermined thickness, and thus a bright line can be improved even if a gap is formed at boundaries between a plurality of micro LED modules.

### TECHNICAL FIELD

The present disclosure relates to a micro LED module that is capable of solving the problem of a bright line in which LED light leaks through a gap that may be formed at a boundary between a plurality of micro LED modules constituting a display device and only the boundary between the micro LED modules appears bright and a display device including the same.

### BACKGROUND ART

As an information society develops, a demand for a display device is also increasing in various forms. In response thereto, recent display devices include a liquid crystal display (LCD), a field emission display (FED), a plasma display panel (PDP), an electroluminescent device, and the like.

Currently, representative major commercialized display devices are LCDs and OLEDs (organic light emitting diodes). However, LCDs are not self-luminous and thus require a backlight unit configured to emit light, which may make it difficult to provide flexibility, while OLEDs are self-luminous, but have problems of a short lifespan and low mass production yield.

Recently, display devices including a plurality of micro LEDs, wherein the size of chips constituting one pixel is less than 100 micrometers, are under development. Since micro LEDs are self-luminous displays, they do not require separate backlights or color filters and are beneficial for flexibility because they use various types of materials as substrates. In addition, micro LEDs may pass the same amount of light with less power consumption due to the thin structure thereof and thus have the advantage of higher power consumption efficiency compared to LCDs and OLEDs due to the structural advantages thereof.

Micro LEDs are widely used to implement large screens in large spaces such as exhibition halls or event halls for corporate marketing and advertising. In particular, it is possible to provide large screens by disposing a plurality of micro LED modules and thus reduce manufacturing costs and enable easy disassembly and assembly as needed.

However, a plurality of micro LED modules is disposed to implement large screens and thus gaps may occur at the boundaries between the modules. In addition, the LED light leaks through the gaps, disadvantageously causing only the boundaries between the modules to appear bright and causing the entire screen to appear evenly.

This problem is called “bright line”. Furthermore, as several to hundreds of micro LED modules need to be disposed to provide large screens, such a problem becomes more serious. Therefore, there is a need for methods capable of reducing bright lines.

### DISCLOSURE

### Technical Task

One technical task of the present disclosure is to provide a micro LED module and a display device including the same, and more specifically, a micro LED module which is capable of reducing bright lines although a gap occurs at a boundary between a plurality of micro LED modules because the micro LED module contains an optical material including a transparent polymer material on the upper surface of a black film and the polymer material has a high refractive index or a greater thickness than a predetermined level, and a display device including the same.

Another technical task of the present disclosure is to provide a micro LED module that is capable of preventing a black film from being peeled off or being damaged by the optical material provided on the upper surface of the black film and thus preventing a deterioration in image quality caused by the difference in brightness on the screen and a display device including the same.

The technical tasks of the present disclosure are not limited to the technical tasks described above and other technical tasks not described herein may be clearly understood by a person having ordinary skill in the technical field to which the present disclosure pertains from the description below.

### Technical Solutions

In one technical aspect of the present disclosure, provided is a micro LED module including a unit substrate, a plurality of micro LED chips mounted on an upper surface of the unit substrate, a protective film covering an upper surface of the unit substrate and the micro LED chips, a black film provided on an upper surface of the protective film; and an optical material provided on an upper surface of the black film, wherein the optical material comprises a transparent polymer material.

The polymer material may have a refractive index of at least 1.3.

The polymer material may have a thickness of at least 5 micrometers (um).

The polymer material may contain at least one of polyethylene terephthalate (PET), polypropylene (PP), polyethylene (PE), ethylene vinyl acetate (EVA), polyimide (PI), epoxy, acryl, or silicone.

In another technical aspect of the present disclosure, provided is a display device including an installation bracket, and a plurality of micro LED modules tiled in a grid pattern on the installation bracket, wherein the micro LED module includes a unit substrate, a plurality of micro LED chips mounted on an upper surface of the unit substrate, a protective film covering an upper surface of the unit substrate and the micro LED chips, a black film provided on an upper surface of the protective film, and an optical material provided on an upper surface of the black film, wherein the optical material comprises a transparent polymer material.

The polymer material may have a refractive index of at least 1.3.

The polymer material may have a thickness of at least 5 micrometers (um).

The polymer material may contain at least one of polyethylene terephthalate (PET), polypropylene (PP), polyethylene (PE), ethylene vinyl acetate (EVA), polyimide (PI), epoxy, acryl, or silicone.

### Advantageous Effects

The micro LED module and the display device including the same according to one embodiment of the present disclosure are capable of reducing bright lines although a gap occurs at a boundary between a plurality of micro LED modules because the micro LED module contains an optical material including a transparent polymer material on the upper surface of a black film and the polymer material has a high refractive index or a greater thickness than a predetermined level.

In addition, the micro LED module and a display device including the same are capable of preventing a black film from being peeled off or being damaged by the optical material provided on the upper surface of the black film and thus preventing a deterioration in image quality caused by the difference in brightness on the screen.

The scope to which the present disclosure may be further applied will be clearly understood from the detailed description below. Those skilled in the art will clearly appreciate that various modifications, additions and substitutions are possible and thus It should be understood that the detailed description and specific embodiments, such as preferred embodiments of the present disclosure, are merely provided for illustration.

### DESCRIPTION OF DRAWINGS

FIG. 1 is a block diagram illustrating each configuration of a display device according to embodiments;

FIG. 2 is an exploded perspective view illustrating the display device according to an embodiment of the present disclosure;

FIG. 3 is an exploded perspective view illustrating a micro LED module according to an embodiment of the present disclosure;

FIG. 4 is a side view illustrating the micro LED module according to an embodiment of the present disclosure; and

FIGS. 5 to 8 are sectional views taken along A-A′ of FIG. 2, illustrating a variety of embodiments of improving brightness through the micro LED module according to one embodiment of the present disclosure.

### BEST MODE FOR DISCLOSURE

Description will now be given in detail according to exemplary embodiments disclosed herein, with reference to the accompanying drawings. The same or equivalent components may be provided with the same reference numbers, and description thereof will not be repeated. As used herein, the suffixes “module” and “part” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification. As such, the present disclosure should be construed to extend to any alterations, equivalents and substitutes in addition to those which are particularly set out in the accompanying drawings.

Although the terms first, second, etc. may be used herein to describe various elements, these elements should not be limited by these terms. These terms are generally only used to distinguish one element from another.

It will be understood that when an element is referred to as being “connected with” another element, the element can be directly connected with the other element or intervening elements may also be present. In contrast, it will be understood that when an element is referred to as being “directly connected with” another element, there are no intervening elements present.

A singular representation may include a plural representation unless it represents a definitely different meaning from the context.

The terms such as “include” or “have” used herein are intended to indicate that features, numbers, steps, operations, elements, components, or combinations thereof used in the following description exist and it should be thus understood that the possibility of existence or addition of one or more different features, numbers, steps, operations, elements, components, or combinations thereof is not excluded.

In one example, a display device described herein is, for example, an intelligent display device in which a computer support function is added to a broadcast reception function. As an Internet function is added while being faithful to the broadcast reception function, the display device may be provided with a more convenient interface for use, such as a handwriting-type input device, a touch screen, or a spatial remote control. In addition, the display device is also able to perform functions such as e-mailing, web browsing, banking, or gaming by connecting to the Internet and a computer with support of a wired or wireless Internet function. Standardized general purpose OS may be used for such various functions.

Accordingly, the display device described herein may freely add or delete various applications on a general-purpose OS kernel, for example, and thus may perform various user-friendly functions. More specifically, the display device may be, for example, a network TV, a HBBTV, a smart TV, or the like, and may be applied to a smartphone in some cases.

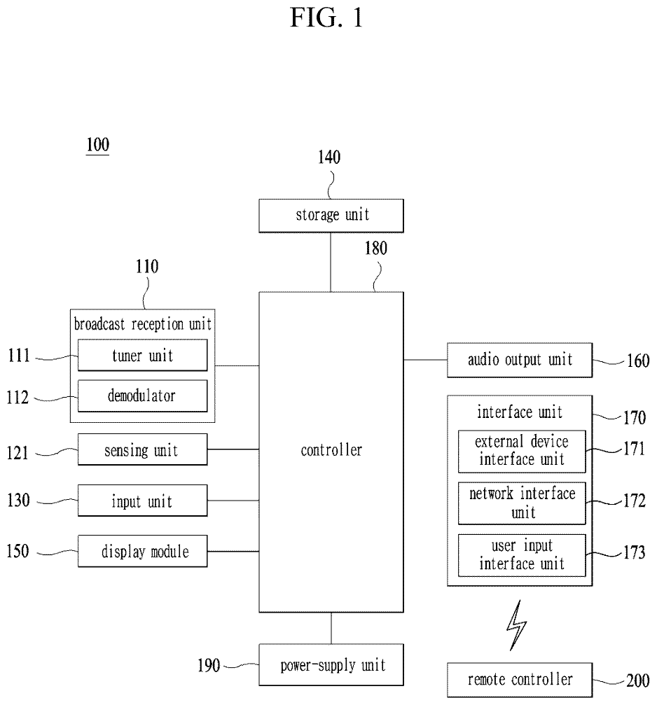

FIG. 1 is a block diagram illustrating each configuration of a display device 100 according to embodiments. Referring to FIG. 1, a display device 100 may include a broadcast receiving unit 110, a sensing unit 120, an external device interface unit 171, a network interface unit 172, a storage unit 140, a user input interface unit 173, an input unit 130, a controller 180, a display module 150, an audio output unit 160, and/or a power supply unit 190.

The broadcast receiving unit 110 may include a tuner 111 and a demodulator 112.

Meanwhile, unlike the drawing, the display device 100 may include only the external device interface unit 171 and the network interface unit 172 among the broadcast receiving unit 110, the external device interface unit 171, and the network interface unit 172. That is, the display device 100 may not include the broadcast receiving unit 110.

The tuner unit 111 may select a broadcast signal corresponding to a channel selected by a user or all pre-stored channels from broadcast signals received through an antenna (not shown) or a cable (not shown). The tuner unit 111 may convert the selected broadcast signal into an intermediate frequency signal or a baseband video or audio signal.

For example, if the selected broadcast signal is a digital broadcast signal, the tuner unit 111 may convert the selected broadcast signal into a digital IF signal (DIF). If the selected broadcast signal is an analog broadcast signal, the tuner unit 111 may convert it into an analog baseband video or audio signal (CVBS/SIF). That is, the tuner unit 111 may process a digital broadcast signal or an analog broadcast signal. The analog baseband video or audio signal (CVBS/SIF) outputted from the tuner unit 111 may be directly inputted to the controller 180.

On the other hand, the tuner unit 111 may sequentially select broadcast signals of all stored broadcast channels through a channel memory function from the received broadcast signals and convert them into intermediate frequency signals or baseband video or audio signals.

Meanwhile, the tuner unit 111 may include a plurality of tuners to receive broadcast signals of a plurality of channels. Alternatively, a single tuner that simultaneously receives broadcast signals of a plurality of channels is also available.

The demodulator 112 may perform a demodulation operation by receiving the digital IF signal (DIF) converted by the tuner 111. The demodulator 112 may output a stream signal (TS) after performing demodulation and channel decoding. In this case, the stream signal may be a signal obtained by multiplexing a video signal, an audio signal, and/or a data signal.

The stream signal outputted from the demodulator 112 may be inputted to the controller 180. The controller 180 may output a video and an audio through the display module 150 and the audio output unit 160 after performing demultiplexing, audio/video signal processing, and the like.

The sensing unit 120 refers to a device that detects or senses a change inside or outside the display device 100. For example, it may include at least one of a proximity sensor, an illumination sensor, a touch sensor, an infrared (IR) sensor, an ultrasonic sensor, an optical sensor (e.g., a camera), a voice sensor (e.g., a microphone), a battery gauge, an environmental sensor (e.g., a humidity meter, a thermometer, etc.).

The controller 180 may check a state of the display device 100 based on the information collected by the sensing unit 120 and inform a user of it when a problem occurs or adjust it by itself to maintain a best state.

In addition, the controller 180 may provide an optimal viewing environment by controlling a content, image quality, size, etc. of a video provided to the display module 180 differently depending on a viewer, an ambient illuminance, and the like detected by the sensing unit. As smart TVs advance, the number of functions installed on display devices increases, and the sensing unit 20 is also increasing together with the functions.

The input unit 130 may be provided on one side of a body of the display device 100. For example, the input unit 130 may include a touch pad, a physical button, and the like. The input unit 130 may receive various user commands related to operations of the display device 100 and transmit control signals corresponding to the inputted commands to the controller 180.

Recently, as a bezel of the display device 100 decreases in size, many display devices 100 tend to minimize the input unit 130 in the form of physical buttons exposed to the outside. Instead, minimum physical buttons are located on a rear or side surface and a user input may be received through a touch pad, the user input interface unit 173, or a remote controller 200 to be described later.

The storage unit 140 may store a program for each signal processing and control in the controller 180, or may store a signal-processed video, audio, or data signal. For example, the storage unit 140 may store application programs designed to perform various tasks which may be processed by the controller 180, and selectively provide some of the stored application programs upon request of the controller 180.

The program and the like stored in the storage unit 140 may not be particularly limited as long as they can be executed by the controller 180. The storage unit 140 may perform a function of temporarily storing a video, audio, or data signal received from an external device through the external device interface unit 171. The storage unit 140 may store information on a prescribed broadcast channel through a channel memory function such as a channel map.

Although FIG. 1 shows an embodiment in which the storage unit 140 is provided separately from the controller 180, the scope of the present disclosure is not limited thereto, and the storage unit 140 may be included in the controller 180.

The storage unit 140 may include at least one of a volatile memory (e.g., DRAM, SRAM, SDRAM, etc.) or a nonvolatile memory (e.g., a flash memory, a Hard Disk Drive (HDD), a Solid-State Drive (SSD), etc.).

The display module 150 may generate a driving signal by converting a video signal, a data signal, an OSD signal, and a control signal processed by the controller, or a video signal, a data signal, a control signal, and the like received from the interface unit 171.

In addition, the display module 150 may include a micro LED module according to one embodiment of the present disclosure described below.

The display module 150 may include a flexible display, or the like, and may also include a three-dimensional (3D) display. The 3D display module 150 may be classified into a glasses-free type and a glasses type.

The display device 100 may include a display module 150 that occupies most of the front surface area and a case that covers the rear surface of the display module 150 to package the display module 150.

The LCD that was generally used in the prior art receives light through a backlight unit because the LCD has difficulty spontaneously emitting light. The backlight unit is an element configured to evenly supply light from a light source to a liquid crystal disposed on the front surface. As the backlight unit becomes thinner, it becomes possible to implement thin LCDs, but it is difficult to implement the backlight unit with a flexible material, and it is difficult to supply light evenly to the liquid crystal although the backlight unit is flexible, which disadvantageously causes the brightness of the screen to change.

On the other hand, LEDs (light emitting diodes) may be designed to be flexible without using a backlight unit since each element constituting a pixel spontaneously emits light. In addition, it is possible to implement a flexible display module 150 since each element spontaneously emits light and the brightness is not affected even if the positional relationship with the adjacent element changes.

The LED panel uses one LED element in each pixel and thus reduces the size of the LED element compared to the prior art and implements a flexible display module 150. In particular, in the micro LED of the present disclosure described below, the size of the chips constituting one pixel may be set to 100 micrometers (um) or less.

The display module 150 includes a coupling magnet, a first power supply unit, and a first signal module.

A side of the display module 150 at which the image is displayed may be referred to as the “front”. When the display module 150 displays the image, the side of the display module 150 at which no image is shown may be referred to as the “rear”. Meanwhile, the display module 150 is configured as a touchscreen and may be used as an input unit in addition to an output unit.

The audio output unit 160 receives an input of a signal audio-processed by the controller 180 and outputs it as an audio.

The interface unit 170 serves as a passage with various types of external devices connected to the display device 100. The interface unit 170 may include a wireless system using an antenna as well as a wired system for transmitting and receiving data through a cable.

The interface unit 170 may include at least one of a wired/wireless headset port, an external charger port, a wired/wireless data port, a memory card port, a port for connecting a device having an identification module, an audio Input/Output (I/O) port, a video Input/Output (I/O) port, an earphone port, etc.

As an example of the wireless system, the above-described broadcast receiving unit 110 may be included, and not only a broadcast signal but also a mobile communication signal, a short-range communication signal, a wireless Internet signal, and the like may be included.

The external device interface unit 171 may transmit or receive data to or from a connected external device. To this end, the external device interface unit 171 may include an A/V input/output unit (not shown).

The external device interface unit 171 may be connected to an external device such as a Digital Versatile Disk (DVD), a Blu-ray, a game device, a camera, a camcorder, a computer (a notebook), a set-top box, and the like by wire or wirelessly, and may perform input/output operations with the external device.

In addition, the external device interface unit 171 may establish a communication network with various remote controllers 200 to receive control signals related to the operation of the display device 100 from the remote controller 200 or transmit data related to the operation of the display device 100 to the remote controller 200.

The external device interface unit 171 may include a wireless communication unit (not shown) for short-range wireless communication with another electronic device. Through the wireless communication unit (not shown), the external device interface unit 171 may exchange data with an adjacent mobile terminal. Particularly, in a mirroring mode, the external device interface unit 171 may receive device information, executed application information, application image, and the like from the mobile terminal.

The network interface unit 172 may provide an interface for connecting the display device 100 to a wired/wireless network including an Internet network. For example, the network interface unit 172 may receive content or data provided by Internet, a content provider, or a network operator over a network. Meanwhile, the network interface unit 172 may include a communication module (not shown) for connection with a wired/wireless network.

The external device interface unit 171 and/or the network interface unit 172 may include a communication module for short-range communication such as Wireless-Fidelity (Wi-Fi), Bluetooth, Bluetooth Low Energy (BLE), Zigbee, and Near Field Communication (NFC), a communication module for cellular communication such as Long-Term Evolution (LTE), LTE-Advance (LTE-A), Code Division Multiple Access (CDMA), Widband CDMA (WCDMA), Universal Mobile Telecommunications System (UMTS), Wireless Broadband (WiBro), and the like.

The user input interface unit 173 may transmit a signal inputted by a user to the controller 180, or transmit a signal from the controller 180 to the user. For example, it may transmit/receive a user input signal such as power on/off, channel selection, screen setting, and the like to/from the remote controller 200, forward a user input signal inputted from a local key (not shown) such as a power key, a channel key, a volume key, a setting value, and the like to the controller 180, forward a user input signal inputted from a sensor unit (not shown) that senses a user's gesture to the controller 180, or transmit a signal from the controller 180 to the sensor unit.

The controller 180 may include at least one processor, and may control the overall operation of the display device 100 by using a processor included therein. Here, the processor may include a general processor such as a Central Processing Unit (CPU). Of course, the processor may include a dedicated device such as an ASIC or another hardware-based processor.

The controller 180 may generate and output a signal for a video or audio output by demultiplex a stream inputted through the tuner 111, the demodulator 112, the external device interface unit 171, or the network interface unit 172 or processing the demultiplexed signals.

The video signal video-processed by the controller 180 may be inputted to the display module 150 and displayed as a video corresponding to the video signal. In addition, the video signal video-processed by the controller 180 may be inputted to an external output device through the external device interface unit 171.

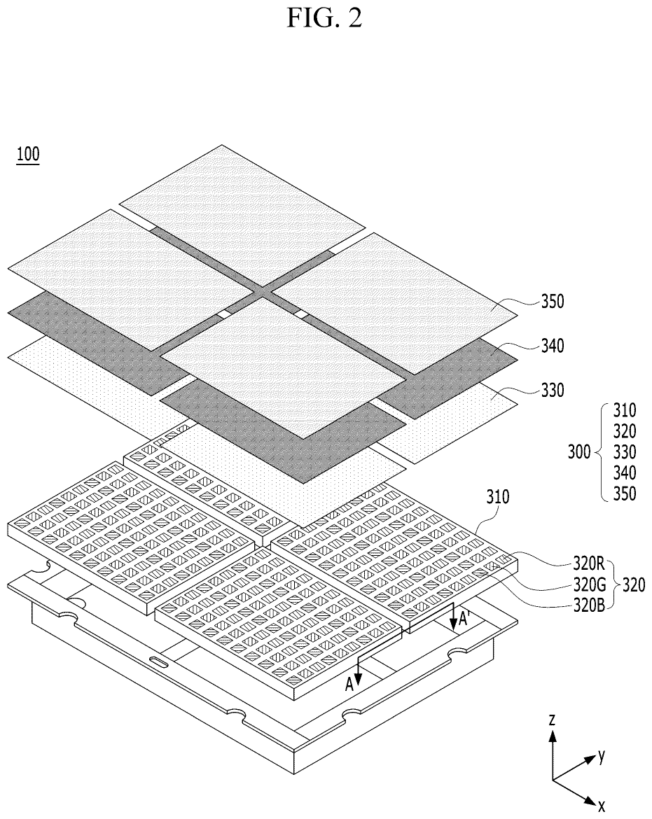

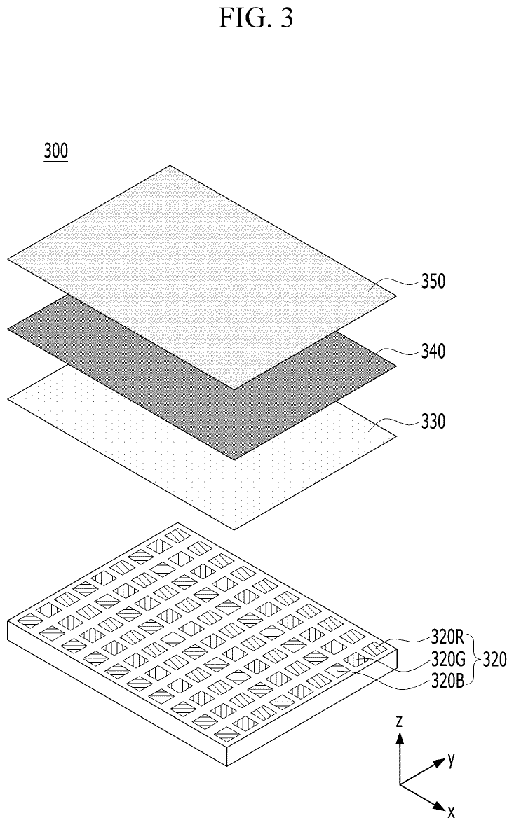

The audio signal processed by the controller 180 may be outputted to the audio output unit 160. Also, the audio signal processed by the controller 180 may be inputted to an external output device through the external device interface unit 171. Although not shown in FIG. 2, the controller 180 may include a demultiplexing unit, a video processing unit, and the like. This will be described later with reference to FIG. 3.

Besides, the controller 180 may control the overall operation of the display device 100. For example, the controller 180 may control the tuner 111 to select (e.g., tune) a broadcast corresponding to a channel selected by a user or a pre-stored channel.

In addition, the controller 180 may control the display device 100 by a user command inputted through the user input interface unit 173 or an internal program. Meanwhile, the controller 180 may control the display module 150 to display an image. In this case, the image displayed on the display module 150 may be a still image or a moving image, and may be a 2D image or a 3D image.

Meanwhile, the controller 180 may display a predetermined 2D object in the image displayed on the display module 150. For example, the object may include at least one of a connected web screen (e.g., newspaper, magazine, etc.), an Electronic Program Guide (EPG), one of various menus, a widget, an icon, a still image, a moving image, and texts.

Meanwhile, the controller 180 may modulate and/or demodulate a signal using an Amplitude Shift Keying (ASK). Here, the amplitude shift modulation (ASK) may mean a method of modulating a signal by varying the amplitude of a carrier wave according to a data value or restoring an analog signal to a digital data value according to the amplitude of the carrier wave.

For example, the controller 180 may modulate a video signal using Amplitude Shift Keying (ASK) and transmit it through a wireless communication module.

For example, the controller 180 may demodulate and process a video signal received through a wireless communication module using Amplitude Shift Keying (ASK).

Through this, the display device 100 may easily transmit and receive signals to and from other adjacent image display devices without using a unique identifier such as a Media Access Control (MAC) address or a complex communication protocol such as TCP/IP.

Meanwhile, the display device 100 may further include a photographing unit (not shown). The photographing unit may photograph a user. The photographing unit may be implemented with a single camera, but is not limited thereto, and may also be implemented with a plurality of cameras. Meanwhile, the photographing unit may be embedded in an upper portion of the display module 150 of the display device 100 or separately disposed. Image information photographed by the photographing unit may be inputted to the controller 180.

The controller 180 may recognize a user's location based on an image photographed by the photographing unit. For example, the controller 180 may recognize a distance (e.g., a z-axis coordinate) between the user and the display device 100. In addition, the controller 180 may recognize an x-axis coordinate and a y-axis coordinate in the display module 150 corresponding to the user's location.

The controller 180 may detect a user's gesture based on an image photographed by the photographing unit, each signal sensed from the sensor unit, or a combination thereof.

The power supply unit 190 may supply corresponding power to the display device 100 overall. In particular, power may be supplied to the controller 180, which may be implemented in the form of a System-On-Chip (SOC), the display module 150 for displaying an image, the audio output unit 160 for audio output, etc.

Specifically, the power supply unit 190 may include a converter (not shown) that converts AC power into DC power, and a Dc/Dc converter (not shown) that converts a level of the DC power.

Meanwhile, the power supply unit 190 serves to receive power from the outside and distribute the power to each component. The power supply unit 190 may use a method of supplying AC power by directly connecting with external power, and a power supply unit 190 usable in a manner of charging a battery included therein may be included.

In the former case, a wired cable is connected and used, and movement is difficult or a range of movement is limited. In the latter case, although it is free to move, the weight and volume increase as much as the battery, and for charging, it should be connected to a power cable directly for a predetermined time or combined with a charging holder (not shown) that supplies power.

The charging holder may be connected to the display device through a terminal exposed to the outside, or a built-in battery may be charged when the charging holder is approached using a wireless method.

The remote controller 200 may transmit a user input to the user input interface 173. To this end, the remote controller 200 may use Bluetooth, Radio Frequency (RF) communication, Infrared Radiation (IR) communication, Ultra-WideBand (UWB), ZigBee, etc. In addition, the remote controller 200 may receive a video, an audio, a data signal, or the like outputted from the user input interface unit 173 and the received image, audio, data signal or the like may be displayed or outputted by the remote controller 200.

Meanwhile, the above-described display device 100 may include a stationary or mobile digital broadcast receiver capable of receiving digital broadcasting.

Meanwhile, the block diagram of the display device 100 shown in FIG. 1 is only a block diagram for an embodiment of the present disclosure, and each component of the block diagram may be integrated, added, or omitted depending on the specifications of the display device 100 that is actually implemented.

That is, two or more components may be combined or integrated into one component, or one component may be subdivided into two or more components as necessary. In addition, a function performed in each block is for describing an embodiment of the present disclosure, and a specific operation or device does not limit the scope of rights of the present disclosure.

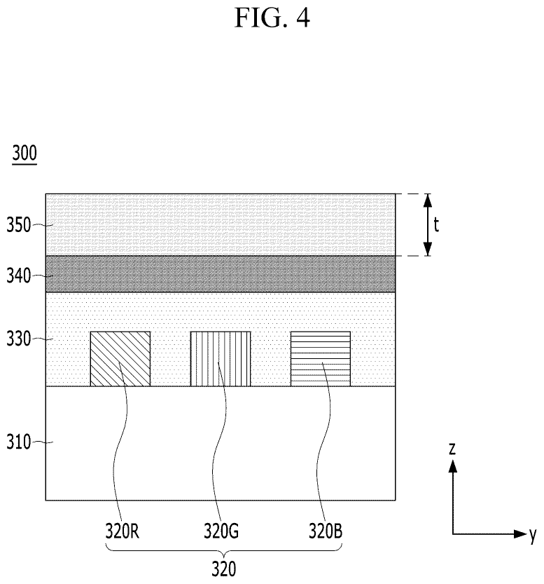

FIG. 2 is an exploded perspective view illustrating a display device 100 according to an embodiment of the present disclosure. FIG. 3 is an exploded perspective view illustrating a micro LED module 300 according to an embodiment of the present disclosure. FIG. 4 is a side view illustrating the micro LED module 300 according to an embodiment of the present disclosure.

First, referring to FIGS. 3 and 4, the micro LED module 300 according to one embodiment of the present disclosure may include a unit substrate 310, a plurality of micro LED chips 320, a protective film 330, a black film 340, and an optical material 350.

Here, the unit substrate 310 may be a flexible substrate. For example, in order to implement a flexible display device 100, the unit substrate 310 may include glass or polyimide (PI). In addition, any insulating and flexible material, such as PEN (polyethylene naphthalate) or PET (polyethylene terephthlate), may be used. In addition, the unit substrate 310 may be formed of either a transparent material or an opaque material.

The plurality of micro LED chips 320 may be mounted on the upper surface of the unit substrate 310. Here, each micro LED chip 320 may include a plurality of pixels disposed in the row direction (x-axis direction) or the column direction (y-axis direction) of the unit substrate 310. For example, the plurality of pixels may include a red (hereinafter referred to as “R”) pixel 320R, a green (hereinafter referred to as “G”) pixel 320G, and a blue (hereinafter referred to as “B”) pixel 320B. In addition, the R pixel 320R, the G pixel 320G, and the B pixel 320B may constitute one micro LED chip 320. In addition, the micro LED chip 320 of the present disclosure may further include a white (hereinafter referred to as “W”) pixel.

The micro LED module 300 according to one embodiment of the present disclosure may include a unit substrate 310 and a protective film 330 covering the plurality of micro LED chips 320 mounted on the upper surface of the unit substrate 310. Here, the micro LED chips 320 may be coated with the protective film 330 to cover the micro LED chips 320 emitting light with the protective film 330.

In addition, a black film 340 may be provided on the upper surface of the protective film 330. The black film 340 may function to improve the black of light emitted through the micro LED chip 320 of the micro LED module 300 according to one embodiment of the present disclosure. In addition, a visual blackout effect may be obtained when power to the display device 100 of the present disclosure is interrupted. In addition, the black film may function to improve the straightness of light emitted from the micro LED chip 320 in order to reduce the bright lines that may occur at the boundary between the micro LED modules 300 described below.

In addition, the micro LED module 300 of the present disclosure may contain an optical material 350 provided on the upper surface of the black film 340. Here, the optical material 350 may include a transparent polymer material. In addition, the polymer material may have a refractive index of at least 1.3 and a thickness (t) at least 5 micrometers (um). As a result, it is possible to reduce the bright lines that may occur at the boundary between the micro LED modules 300 described below.

In addition, the optical material 350 provided on the upper surface of the black film 340 has an effect of improving the structural stability and the image quality of the micro LED module 300. This effect is achieved by providing the optical material 350 on the upper surface of the black film 340 having a thickness in micrometers (um) to prevent the black film 340 from being peeled off or damaged.

That is, as described above, the black film 340 functions to improve the black of the light emitted through the micro LED chip 320 and obtain a visual blackout effect. Therefore, when the black film 340 is peeled off or damaged, it cannot perform the functions. As a result, a difference in brightness may occur partially and may create stains on the screen, which may result in a deterioration in image quality.

Therefore, a layer to protect the black film 340 is formed using the optical material 350 provided on the upper surface of the black film 340, thereby solving the problem of deterioration in image quality due to damage to the black film 340.

In addition, the transparent polymer material in the micro LED module 300 according to one embodiment of the present disclosure may contain at least one of polyethylene terephthalate (PET), polypropylene (PP), polyethylene (PE), ethylene vinyl acetate (EVA), polyimide (PI), epoxy, acryl, or silicone.

In addition, the polymer material of the present disclosure may include another polymer material, a resin material or a copolymer thereof having similar properties to the polymer material described above. That is, the polymer material of the present disclosure may include any polymer material that is transparent, transmits light, and has a refractive index greater than the refractive index of air.

FIG. 2 is an exploded view of a display device 100 according to an embodiment of the present disclosure, and the display device 100 according to an embodiment of the present disclosure may include an installation bracket 360 and a plurality of micro LED modules 300 tiled in a grid pattern on the installation bracket 360.

Here, the number of the micro LED modules 300 is not limited to the number shown in FIG. 2 and several to several hundreds of micro LED modules may be disposed to constitute the display device 100 of the present disclosure.

In addition, the installation bracket 360 may function to support a plurality of micro LED modules 300 tiled in a grid pattern. In addition, the installation bracket 360 according to one embodiment of the present disclosure may be implemented as a frame assembly. That is, the installation bracket 360 may be formed by assembling a plurality of frames to support a plurality of micro LED modules 300 that may be disposed in various numbers as described above.

In addition, the micro LED module 300 may include a unit substrate 310, a plurality of micro LED chips 320 mounted on the upper surface of the unit substrate 310, a protective film 330 covering the upper surface of the unit substrate 310 and the plurality of micro LED chips 320, a black film 340 provided on the upper surface of the protective film 330, and an optical film 350 provided on the upper surface of the black film 340.

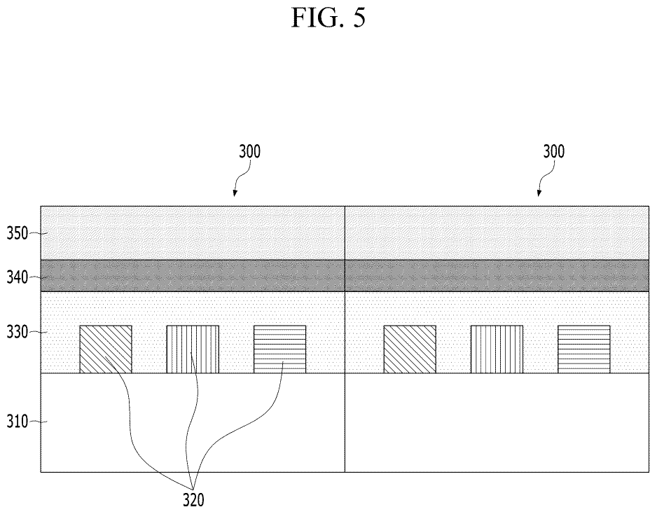

FIGS. 5 to 8 are sectional views taken along A-A′ of FIG. 2, illustrating a variety of embodiments of improving brightness through the micro LED module according to one embodiment of the present disclosure.

FIG. 5 illustrates an embodiment in which a gap is not formed at the boundary between micro LED modules 300. Referring to FIG. 2, when a plurality of micro LED modules 300 are disposed in a display device 100 according to an embodiment of the present disclosure, it is preferable that a gap is not formed at the boundary between the micro LED modules 300.

However, a gap may be formed at the boundary between the micro LED modules 300 during the process. In this case, as described above, light emitted from the micro LED chip 320 leaks through the gap, resulting in a problem in which only the boundary between the micro LED modules 300 appears bright. Therefore, a method of reducing the bright lines using the micro LED module 300 of the present disclosure will be described below.

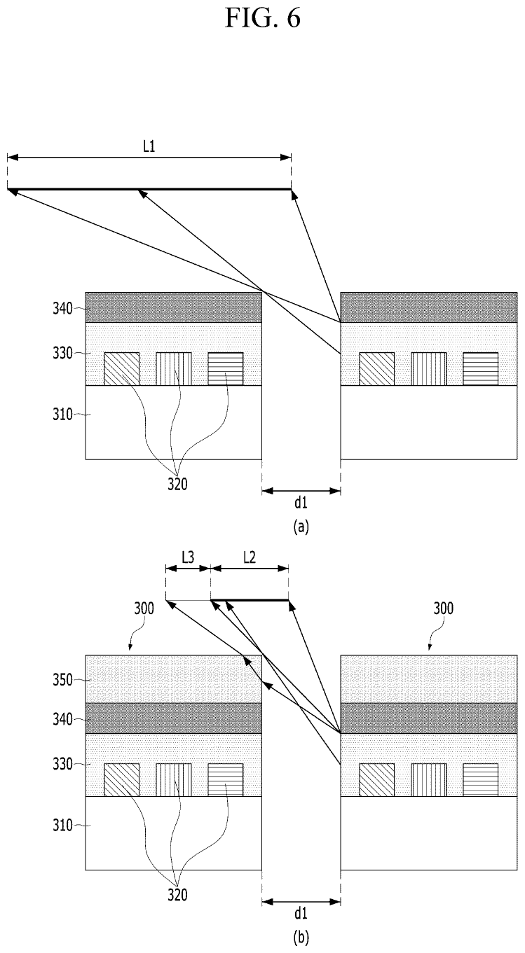

First, FIG. 6 illustrates an embodiment in which bright lines are reduced when a gap (d1) occurs at the boundary between micro LED modules 300. (a) of FIG. 6 illustrates the problem of bright lines when the optical material 350 of the present disclosure is not provided and (b) of FIG. 6 illustrates the reduction of bright lines of the micro LED module 300 provided with the optical material 350 of the present disclosure.

As shown in (a) of FIG. 6, when the optical material 350 of the present disclosure is not provided, the light emitted from the micro LED chip 320 leaks through the gap (d1) and a bright line corresponding to the area L1 is formed.

At this time, the refractive index of the air in the air layer on the upper surface of the black film 340 is 1 and thus the light emitted from the micro LED chip 320 passes straight without refraction and a bright line corresponding to the area LI is formed.

On the other hand, as shown in (b) of FIG. 6, in the micro LED module 300 provided with the optical material 350 on the upper surface of the black film 340, a bright line corresponding to only in the areas L2 and L3, which are shorter than the area L1, is formed although light emitted through the micro LED chip 320 leaks through the gap (d1).

In particular, since the optical material 350 of the present disclosure includes a polymer material having a refractive index of at least 1.3, which is greater than the refractive index of air, light incident on the optical material 350 is refracted by the polymer material having a high refractive index of the present disclosure and travels into the area L3.

At this time, since the intensity of light is weakened while it passes through the optical material 350, the intensity of light in the area L3 due to light passing through the optical material 350 is weaker than that in the area L2. As a result, the bright line may be significantly reduced compared to (a) of FIG. 6, where the optical material 350 is not provided.

Here, as the refractive index increases, the area L3 becomes smaller, which may increase the effect of reducing the bright line. However, when the refractive index is excessively high, the phenomenon in which light passing through the optical material 350 is distorted may occur. Therefore, the polymer material of the present disclosure has a refractive index of at least 1.3, and preferably, not less than 1.3 and not more than 1.6.

In addition, referring to FIG. 4 together, the thickness (t) of the optical material 350 of the present disclosure may be at least 5 micrometers (um). When the thickness (t) of the optical material 350 is excessively small, the optical material 350 may be damaged and thus it is preferable that the thickness (t) of the optical material 350 is at least 5 micrometers (μm).

In addition, as the thickness (t) of the optical material 350 increases, the areas L2 and L3 may become shorter in (b) of FIG. 6, and the intensity of light passing through the optical material 350 may be reduced and thus the effect of reducing the bright line may be increased. However, when the thickness (t) of the optical material 350 is excessively small, the light transmittance may be low, which may reduce the clarity. Therefore, the thickness (t) of the optical material 350 is preferably provided on the upper surface of the black film 340 at an appropriate thickness in consideration of the bright line reduction and clarity.

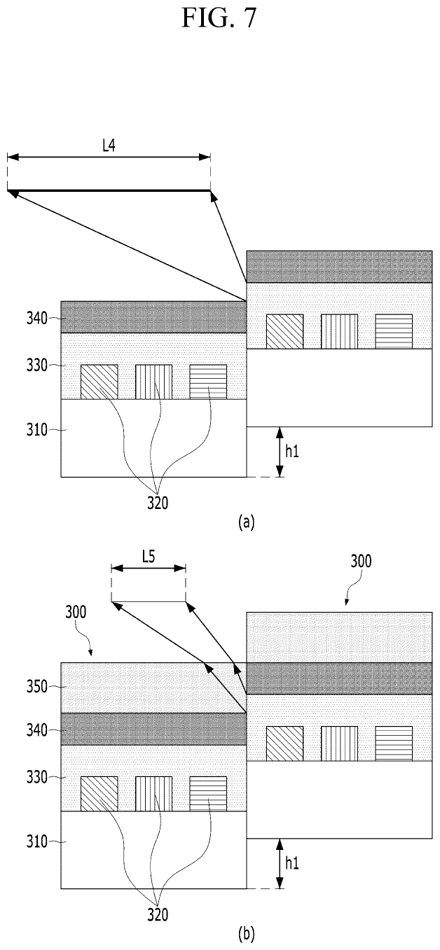

FIG. 7 illustrates an embodiment to reduce the bright line when a height difference (h1) occurs at the boundary between micro LED modules 300. (a) of FIG. 7 illustrates the problem of bright line when the optical material 350 of the present disclosure is not provided, and (b) of FIG. 7 illustrates the bright line reduction of the micro LED module 300 provided with the optical material 350 of the present disclosure.

As shown in (a) of FIG. 7, when the optical material 350 of the present disclosure is not provided, the light emitted through the micro LED chip 320 leaks out due to the height difference (h1) and a bright line is formed only in the area L4.

On the other hand, as shown in (b) of FIG. 7, in the micro LED module 300 provided with the optical material 350 on the upper surface of the black film 340, the light emitted through the micro LED chip 320 is incident on the optical material 350 and refracted, and a bright line corresponding to only the area L5, which is shorter than the area L4, is formed.

In addition, since the intensity of light is reduced when light passes through the optical material 350 as described above, the effect of reducing the bright line may be increased than that illustrated with reference to FIG. 7. In addition, when the thickness (t) of the optical material 350 is provided on the upper surface of the black film 340 having an appropriate thickness of at least 5 micrometers (μm), the effect of reducing the bright line may be further increased.

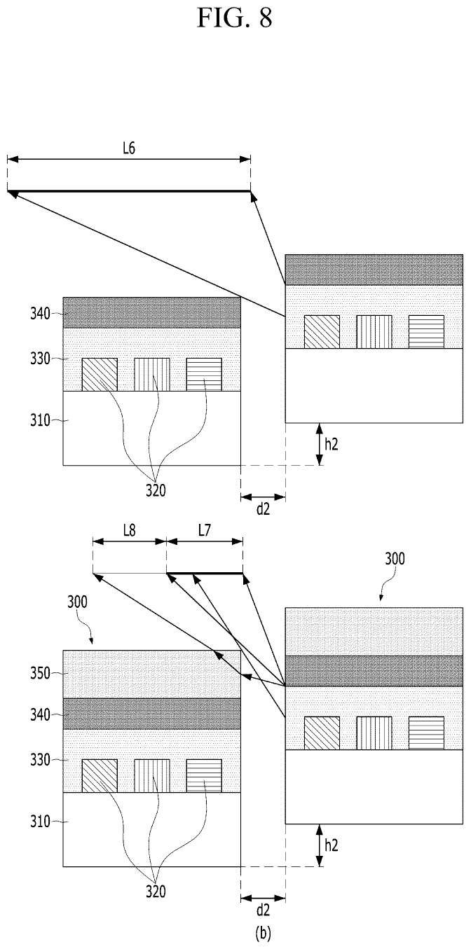

FIG. 8 illustrates an embodiment to reduce the bright line when both the gap (d2) and the height difference (h2) occur at the boundary between the micro LED modules 300. (a) of FIG. 8 illustrates the problem of bright line when the optical material 350 of the present disclosure is not provided, and (b) of FIG. 8 illustrates the bright line reduction of the micro LED module 300 provided with the optical material 350 of the present disclosure.

As shown in (a) of FIG. 8, when the optical material 350 of the present disclosure is not provided, light emitted through the micro LED chip 320 leaks out due to the gap (d2) and the height difference (h2), and a bright line corresponding to the area L6 is formed.

On the other hand, in the micro LED module 300 in which the optical material 350 is provided on the upper surface of the black film 340, as shown in (b) of FIG. 8, even if light emitted through the micro LED chip 320 leaks out due to the gap (d2) and the height difference (h2), bright lines corresponding to only the areas L7 and L8, which are shorter than the L6 area, are formed.

As described above, since the intensity of light passing through the optical material 350 is reduced, the area L8 formed by the light passing through the optical material 350 has weak light intensity and thus a significant bright line reduction effect can be obtained compared to (a) of FIG. 8 where the optical material 350 is not provided. In addition, when the thickness (t) of the optical material 350 is provided on the upper surface of the black film 340 at an appropriate thickness of at least 5 micrometers (um), the effect of bright line reduction can be further increased.

That is, the micro LED module 300 and the display device 100 including the same according to the present disclosure may reduce the bright line problem that may occur when a plurality of micro LED modules 300 are disposed, thereby preventing the phenomenon in which only the boundary between the micro LED modules 300 appears bright and thus reducing the bright line.

The above detailed description is to be construed in all aspects as illustrative and not restrictive. The scope of the present disclosure should be determined by reasonable interpretation of the appended claims and all changes coming within the equivalency range of the present disclosure are intended to be embraced in the scope of the present disclosure.

1. A micro LED module comprising:
a unit substrate;
a plurality of micro LED chips mounted on an upper surface of the unit substrate;
a protective film covering an upper surface of the unit substrate and the micro LED chips;
a black film provided on an upper surface of the protective film; and
an optical material provided on an upper surface of the black film,
wherein the optical material comprises a transparent polymer material.

2. The micro LED module according to claim 1, wherein the polymer material has a refractive index of at least 1.3.

3. The micro LED module according to claim 1, wherein the polymer material has a thickness of at least 5 micrometers (μm).

4. The micro LED module according to claim 1, wherein the polymer material comprises at least one of polyethylene terephthalate (PET), polypropylene (PP), polyethylene (PE), ethylene vinyl acetate (EVA), polyimide (PI), epoxy, acryl, or silicone.

5. A display device comprising:
an installation bracket; and
a plurality of micro LED modules tiled in a grid pattern on the installation bracket,
wherein the micro LED module comprises:
a unit substrate;
a plurality of micro LED chips mounted on an upper surface of the unit substrate;
a protective film covering an upper surface of the unit substrate and the micro LED chips;
a black film provided on an upper surface of the protective film; and
an optical material provided on an upper surface of the black film,
wherein the optical material comprises a transparent polymer material.

6. The display device according to claim 5, wherein the polymer material has a refractive index of at least 1.3.

7. The display device according to claim 5, wherein the polymer material has a thickness of at least 5 micrometers (um).

8. The display device according to claim 5, wherein the polymer material comprises at least one of polyethylene terephthalate (PET), polypropylene (PP), polyethylene (PE), ethylene vinyl acetate (EVA), polyimide (PI), epoxy, acryl, or silicone.
